(19) United States
(12) Patent Application Publication
(10) Pub. No.: US 2007/0132484 A1
(43) Pub. Date: Jun. 14, 2007

(54) Switch circuit and input signal processing circuit

(75) Inventor: Yoji Urayama, Kanagawa (JP)

Correspondence Address: FOLEY AND LARDNER LLP;SUITE 500, 3000 K STREET NW, WASHINGTON, DC, 20007, US

(73) Assignee: NEC ELECTRONICS CORPORATION

(21) Appl. No.: 11/604,217

(22) Filed: Nov. 27, 2006

(30) Foreign Application Priority Data
Nov. 28, 2005 (JP) 2005-341534

(51) Int. Cl. G01N 30/86

(52) U.S. Cl. 327/1

(57) ABSTRACT

A switch circuit includes first switches; and second switches. The first switches and the second switches are alternately arranged one by one, and a semiconductor substrate is of a first conductive type. Each of the first switches comprises a first transistor of a second conductive type which is opposite to that of the semiconductor substrate, and each of the second switches includes a second transistor of the second conductive type, surrounded by an outer well of the second conductive type.

### BACKGROUND OF THE INVENTION

1. Field of the Invention

The present invention relates to a switch circuit and an input signal processing circuit using the switch circuit.

2. Description of the Related Art

An input signal processing circuit is known in which a plurality of video input signals are switched by a switch circuit, and various signal processes are carried out therein. FIG. 1 is a circuit diagram showing a conventional input signal processing circuit 101. The input signal processing circuit 101 is composed of switch circuits 103, amplifying circuits 104 and signal processing circuits 105. The switch circuit 103 has a plurality of analog switches. By operating the plurality of switches, one is selected from among a plurality of video input signals, namely, one R signal, one G signal, or one B signal is selected from among a plurality of R signals, a plurality of G signals, or a plurality of B signals. The amplifying circuit 104 amplifies the selected video input signal. The signal processing circuit 105 carries out a predetermined signal process on the amplified video input signal. The predetermined signal process is, for example, a filtering process such as a y process and a low pass filter.

In the example shown in FIG. 1, the plurality of switch circuit 103, the amplifying circuit 104 and the signal processing circuit 105 are defined as one set, and the sets are provided for the G signal, the R signal and the B signal. One switch circuit 103 is supplied with G1(Y1) to G5(Y5) signals as five elements and selects one element as a G(Y) signal from them. The adjacent switch circuit 103 is supplied with R1(Pr1) to R5(Pr5) signals as five elements and selects one element as an R(Pr) signal from them. And, the switch circuit 103 further adjacent thereto is supplied with B1(Pb1) to B5(Pb5) signals as five elements and selects one element as a B(Pb) signal from them. That is, FIG. 1 shows the conventional input signal processing circuit which has inputs for the RGB video signals of five elements and output for RGB video signal of one element.

FIG. 2 is a circuit diagram showing an example of the configuration of the conventional switch circuit 103. The switch circuit 103 includes n (n is a natural number of 2 or more) analog switches SW (SW1 to SWn). In this example, NMOS transistors 110 are used as the switches SW. For example, about several hundred of analog switches may be provided to switch the video input signals if there are many input elements (n=several hundreds). In many cases, the plurality of switches are arranged relatively close to each other from the viewpoint of the easiness of layout, a relative error between signals, and reduction in an occupied area. Here, the NMOS transistors 110 adjacent to each other are arranged such that their ends on the sides close to each other are separated by a distance d1. The distance of d1 is within the length of one NMOS transistor 110.

FIGS. 3A and 3B are a plan view and a cross sectional view showing the configuration of the switch circuit 103 shown in FIG. 2, respectively. Each of the switches SW (SW1 to SWn) is composed of a P well 111 formed in a P-type substrate 115, and an NMOS r5 transistor 110 formed in the P well 111. The NMOS transistor 110 is composed of two N-type diffusion layers 112 formed in the P well 111, and a gate 113 formed on the P-type substrate 115 between the two N-type diffusion layers 112. The P well 111 is connected to a ground line 116. The P-type substrate 115 is connected to a ground line 117. In this example, there is a possibility that a signal sent to one switch SW, e.g., the switch SW1 flows into another switch SW, e.g., the switch SW2 adjacent thereto through the P-type substrate 115. This is because the P wells 111 including the NMOS transistors 110 and the P-type substrate 115 are electrically connected, and the P wells 111 serving as the back gates of the NMOS transistors 110 are electrically connected to each other. In FIG. 3B, this connection is shown by resistors 119. In particular, if the NMOS transistors are separated by a distance shorter than the length of the three NMOS transistors 110, the effect becomes remarkable. Thus, there is a possibility that a video signal given to the switch SW1, a switching noise generated when the switch is switched, and the like are transferred to the switch SW2 through the P-type substrate 115. That is, crosstalk is generated.

FIG. 4 is a circuit diagram showing another example of the configuration of the conventional switch circuit 103. The switch circuit 103 includes n (n is a natural number of 2 or more) analog switches SW (SW1 to SWn). For example, about several hundred of analog switches may be provided to switch the video input signals (n=several hundreds in this case). In this example, a transfer gate is used as the switch SW in which an NMOS transistor 110 and a PMOS transistor 120 are combined. The plurality of switches are arranged relatively close to each other, as shown in FIG. 2. Here, the NMOS transistors 110 of adjacent two of the switches SW are arranged such that their ends close to each other are separated by a distance d2. The distance of d2 is within two times of the length of the NMOS transistor 110 or PMOS transistor 120.

FIGS. 5A and 5B are a plan view and a cross sectional view showing the configuration of the switch circuit 103 shown in FIG. 4, respectively. Each of the switches SW (SW1 to SWn) is composed of a P well 111 and an N well 121 formed in the P-type substrate 115, an NMOS transistor 110 formed in the P well 111, and a PMOS transistor 120 formed in the N well 121. The NMOS transistor 110 is composed of two N-type diffusion layers 112 formed in the P well 111, and a gate 113 formed on the P-type substrate 115 between the two N-type diffusion layers 112. The P well 111 is connected to a ground line 116. The PMOS transistor 120 is composed of two P-type diffusion layers 122 formed in the N well 121 and a gate 123 formed on the P-type substrate 115 between the two P-type diffusion layers 122. The N well 121 is connected to a power source line 126. The P-type substrate 115 is connected to a ground line 117. In this example, because of the reason similar to the case of FIG. 3, there is a possibility that a signal sent to the NMOS transistor 110 of one switch SW, e.g., the switch SW1 is transferred to the NMOS transistor 110 of the adjacent switch SW, e.g., the switch SW2 through the P-type substrate 115. In particular, if the NMOS transistors are separated by a distance shorter than the length of the three NMOS transistors 110 or PMOS transistors, the effect becomes remarkable. Thus, in this case, there is also a possibility that the video signal given to the switch SW1, a switching noise when the switch is switched, and the like are sent to the switch SW2 through the P-type substrate 115. That is, the crosstalk is generated.

In conjunction with the above description, a semiconductor device is known in Japanese Laid Open Patent Application (JP-P2005-116586A). This conventional semiconductor device has a built-in analog-to-digital converting circuit or digital-to-analog converting circuit, in which digital circuits and switched capacitor filters are provided. In this conventional semiconductor device, the digital circuits and the switched capacitor filters are respectively arranged in a plurality of regions electrically isolated on a substrate. That is, in order to prevent an SN ratio from being deteriorated due to crosstalk noise that is sent through the substrate to the respective circuits, the wells in which the circuits are formed are surrounded by N-type diffusion layers. Thus, P-type substrates and the circuits are electrically separated. In this case, although the circuits are separated from each other, elements are not separated from each other.

Also, Japanese Laid Open Patent Application (JP-A-Heisei, 5-326862) discloses a semiconductor device. In this conventional semiconductor device, a first transistor having a first conductive type channel, and a second transistor having a second conductive type channel opposite to the first conductive type are formed on a semiconductor substrate of the first conductive type. In this conventional semiconductor device, the first transistor is formed in a first well region of the second conductive type formed in the semiconductor substrate. A second well region of the second conductive type is formed in a region different from the first well region where the first transistor is formed on the semiconductor substrate, a third well region of the first conductive type is formed inside the second well region, and the second transistor is formed in the third well region. That is, in order to prevent a latch-up phenomenon caused between FETs adjacent to each other, an N-type well region is formed for electrically separating only the N-channel transistor of CMOS transistors from the P-type substrate.

Also, Japanese Laid Open Patent Application (JP-A-Showa, 61-184063) and Japanese Laid Open Utility Model Application (JU-A-Heisei, 6-23324) disclose image signal switching devices in which a crosstalk between image signals can be avoided when the image signals are switched by adjacent analog switches. In the image signal switching apparatus disclosed in Japanese Laid Open Patent Application (JP-A-Showa, 61-184063), an analog switch circuit as an integrated circuit switches a plurality of image signals. A light emission diode driving circuit displays the switched states of the image signals. A transistor is connected to an input side of the analog switch circuit and is controlled the image signals, which are not selected by the analog switch circuit, to be connected to a ground in response to a display control signal of the light emission diode.

Also, in a high frequency switch circuit disclosed in Japanese Laid Open Utility Model Application (JU-A-Heisei, 6-23324), analog switches are arranged on a printed circuit board, so as for the input terminal to be close. The respective input terminals and ground terminals are connected to each other at short distances and simultaneously connected to connector terminals. Then, they are wired to respective video inputs from the connector terminals of the main printed circuit board connected thereto. Traps of a plurality of parasitic resonance circuits composed of input capacitances of the analog switches and inductances L of wirings are set outside a use frequency band.

In order to reduce the crosstalk, when the structure disclosed in Japanese Laid Open Patent Application (JP-P2005-116586A) or Japanese Laid Open Patent Application (JP-A-Heisei, 5-326862) is applied to the switch circuit 103 as shown in FIGS. 3A and 3B or FIGS. 5A and 5B, the N well regions must be formed for all of the NMOS transistors 110. That is, the N-type diffusion layer region of Japanese Laid Open Patent Application (JP-P2005-116586A) or the N well region (hereafter, also referred to as a “separation well”) of Japanese Laid Open Patent Application (JP-A-Heisei, 5-326862) is required to be provided for each element (the NMOS transistor 110). For this reason, an area per element becomes larger. As a result, when the number of the analog switches is increased to about several hundred, the chip area increases largely.

### SUMMARY OF THE INVENTION

Therefore, an object of the present invention is to provide a switch circuit and an input signal processing circuit containing the switch circuit, in which a crosstalk can be efficiently prevented.

Another object of the present invention is to provide a switch circuit and an input signal processing circuit containing the switch circuit, in which increase in a chip area can be suppressed while the crosstalk is prevented.

In an aspect of the present invention, a switch circuit includes first switches; and second switches. The first switches and the second switches are alternately arranged one by one, and a semiconductor substrate is of a first conductive type. Each of the first switches comprises a first transistor of a second conductive type which is opposite to that of the semiconductor substrate, and each of the second switches includes a second transistor of the second conductive type, surrounded by an outer well of the second conductive type.

Here, the first switch may include a first well of the first conductive type formed in the semiconductor substrate; and the first transistor of the second conductive type formed in the first well.

Also, the second switch may include the outer well formed in the semiconductor substrate; a second well of the first conductive type formed in the outer well; and the second transistor of the second conductive type formed in the second well.

Also, the first well may be connected to a first voltage by a first line, the second well may be connected to the first voltage by a second line, and the outer well may be connected to a second voltage by an outer well line. In this case, each of portions of the semiconductor substrate near the first well and the outer well may be connected to the first voltage.

Also, the first conductive type may be a P type, and the second conductive type may be an N type. Also, the first voltage may be a ground voltage, and the second voltage may be a power source voltage.

Also, the outer well lines of the second switches may be separated from each other in a neighborhood of the outer wells.

Also, the first switch further may include a third well of the second conductive type formed in the semiconductor substrate in a neighborhood of the first well; and the third transistor of the first conductive type formed in the third well.

Also, the second switch may further include a fourth well of the second conductive type formed in the semiconductor substrate in a neighborhood of the outer well; and the fourth transistor of the first conductive type formed in the fourth well.

Also, the first well may be connected to a first voltage by a first line, the second well may be connected to the first voltage by a second line, the outer well may be connected to a second voltage by an outer well line, the third well may be connected to the second voltage by a third line, and the fourth well may be connected to the second voltage by a fourth line. In this case, each of portions of the semiconductor substrate near the first well, the third well, the fourth well and the outer well may be connected to the first voltage.

Also, the first conductive type may be a P type, and the second conductive type may be an N type. The first voltage may be a ground voltage, and the second voltage may be a power source voltage.

Also, the outer well lines of the second switches are separated from each other in a neighborhood of the outer wells.

Also, the first and second lines of the first and second switches are separated from each other in a neighborhood of the first and second wells.

In another aspect of the present invention, an input signal processing circuit includes a switch circuit configured to select one of a plurality of input signals in response to a control signal; and a processing circuit configured to carry out a predetermined process to the selected signal by the switch circuit. The switch circuit includes first switches; and second switches. The first switches and the second switches are alternately arranged one by one, and a semiconductor substrate is of a first conductive type. Each of the first switches comprises a first transistor of a second conductive type which is opposite to that of the semiconductor substrate, and each of the second switches includes a second transistor of the second conductive type, surrounded by an outer well of the second conductive type.

Here, the first switch may include a first well of the first conductive type formed in the semiconductor substrate; and the first transistor of the second conductive type formed in the first well. The second switch may include the outer well formed in the semiconductor substrate; a second well of the first conductive type formed in the outer well; and the second transistor of the second conductive type formed in the second well.

Also, the first well may be connected to a first voltage by a first line, the second well may be connected to the first voltage by a second line, the outer well may be connected to a second voltage by an outer well line, and each of portions of the semiconductor substrate near the first well and the outer well may be connected to the first voltage.

Also, the first switch may further include a third well of the second conductive type formed in the semiconductor substrate in a neighborhood of the first well; and the third transistor of the first conductive type formed in the third well. Also, the second switch may further include a fourth well of the second conductive type formed in the semiconductor substrate in a neighborhood of the outer well; and the fourth transistor of the first conductive type formed in the fourth well.

Also, the first well may be connected to a first voltage by a first line, the second well may be connected to the first voltage by a second line, the outer well may be connected to a second voltage by an outer well line, the third well may be connected to the second voltage by a third line, and the fourth well may be connected to the second voltage by a fourth line.

Also, each of portions of the semiconductor substrate near the first well, the third well, the fourth well and the outer well may be connected to the first voltage.

### BRIEF DESCRIPTION OF THE DRAWINGS

FIG. 1 is a circuit diagram showing a conventional input signal processing circuit;

FIG. 2 is a circuit diagram showing an example of a configuration of a conventional switch circuit;

FIGS. 3A and 3B are a plan view and a cross sectional view showing the configuration of the switch circuit of FIG. 2;

FIG. 4 is a circuit diagram showing the configuration of another conventional switch circuit;

FIGS. 5A and 5B are a plan view and a sectional view showing the configuration of the switch circuit of FIG. 4;

FIG. 6 is a circuit diagram showing a configuration of an input signal processing circuit according to the present invention;

FIGS. 7A and 7B are a plan view and a cross sectional view showing the configuration of a switch circuit according to a first embodiment of the present invention;

FIGS. 8A and 8B are a plan view and a sectional view showing the configuration of the switch circuit according to a second embodiment of the present invention;

FIGS. 9A and 9B are diagrams schematically showing a relation between a power source line and a pad of a semiconductor chip; and

FIG. 10 is a flowchart showing an operation of the input signal processing circuit according to the present invention.

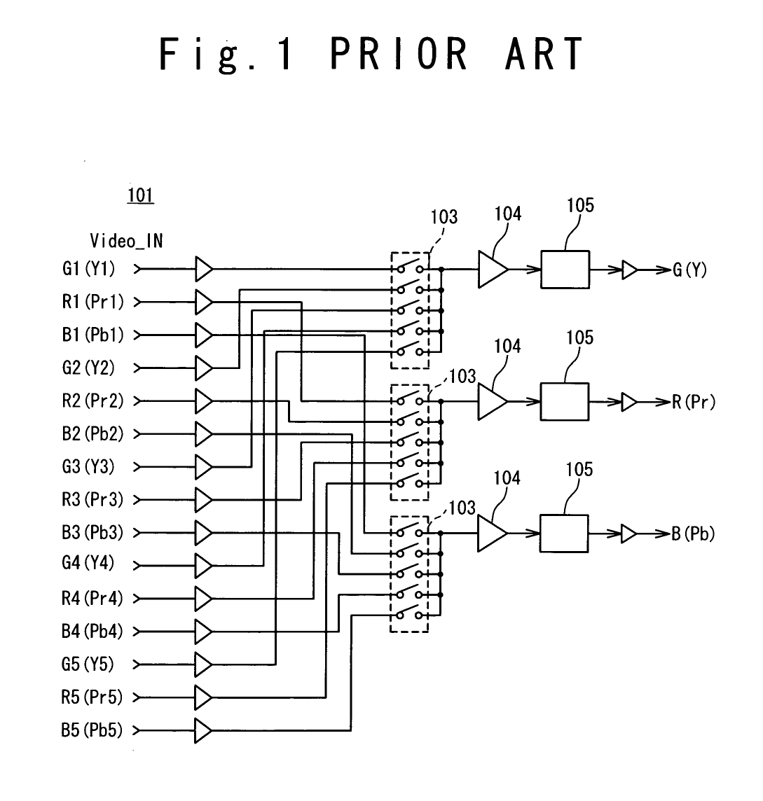

### DESCRIPTION OF THE PREFERRED EMBODIMENTS

Hereinafter, an input signal processing circuit using a switch circuit according to the present invention will be described in detail with reference to the attached drawings.

### First Embodiment

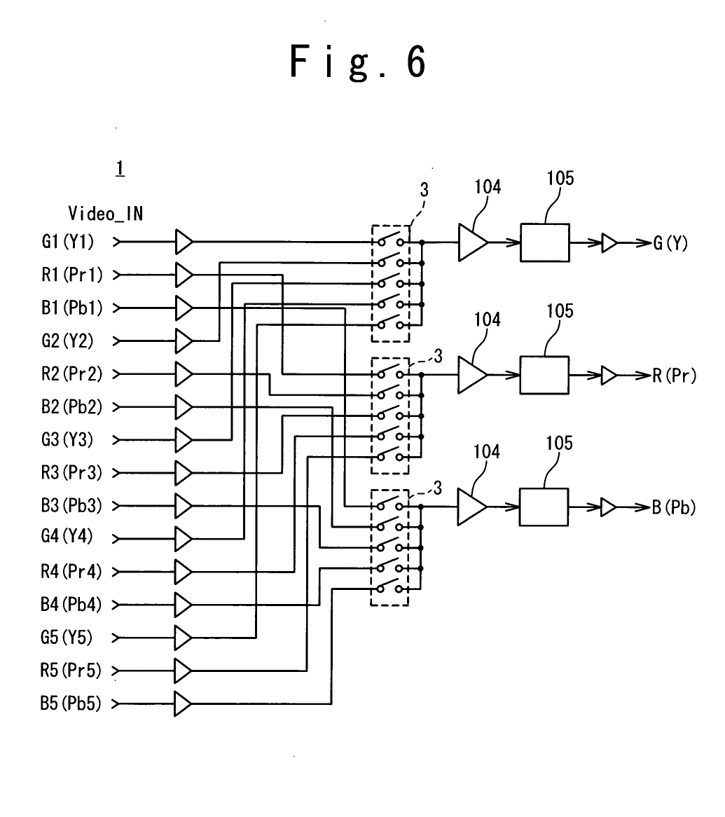

At first, the configuration of the input signal processing circuit with the switch circuit according to the first embodiment of the present invention will be described with reference to FIG. 6. An input signal processing circuit 1 is composed of switch circuits 3, amplifying circuits 104 and signal processing circuits 105. The switch circuit 3 has a plurality of analog switches. By operating the plurality of switches, one is selected from among a plurality of video input signals, namely, one R signal, one G signal, or one B signal is selected from among a plurality of R signals, a plurality of G signals, or a plurality of B signals. The amplifying circuit 104 amplifies the selected video input signal. The signal processing circuit 105 carries out a predetermined signal process on the amplified video input signal. The predetermined signal process is, for example, a filtering process such as a y process and a low pass filter.

In the example shown in FIG. 6, the plurality of switch circuit 3, the amplifying circuit 104 and the signal processing circuit 105 are defined as one set, and the sets are provided for the G signal, the R signal and the B signal. One switch circuit 3 is supplied with G1(Y1) to G5(Y5) signals as five elements and selects one element as a G(Y) signal from them. The adjacent switch circuit 3 is supplied with R1(Pr1) to R5(Pr5) signals as five elements and selects one element as an R(Pr) signal from them. And, the switch circuit 3 further adjacent thereto is supplied with B1(Pb1) to B5(Pb5) signals as five elements and selects one element as a B(Pb) signal from them. That is, FIG. 6 shows the conventional input signal processing circuit which has inputs for the RGB video signals of five elements and output for RGB video signal of one element.

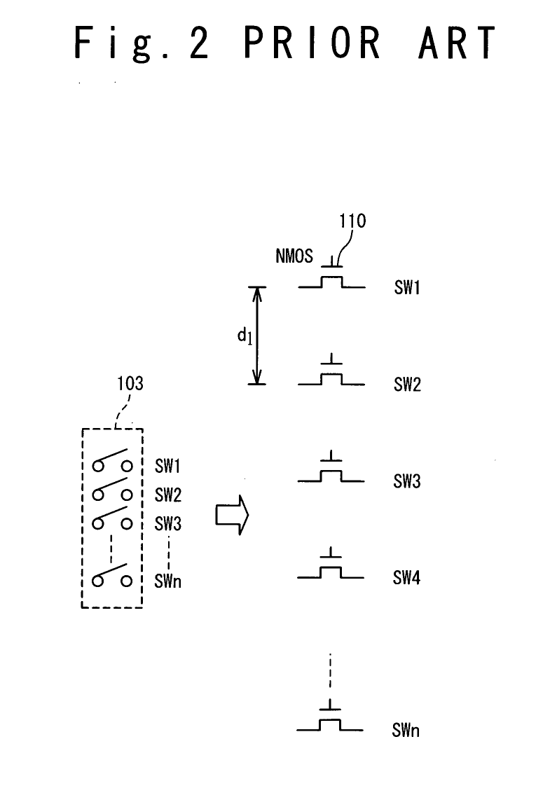

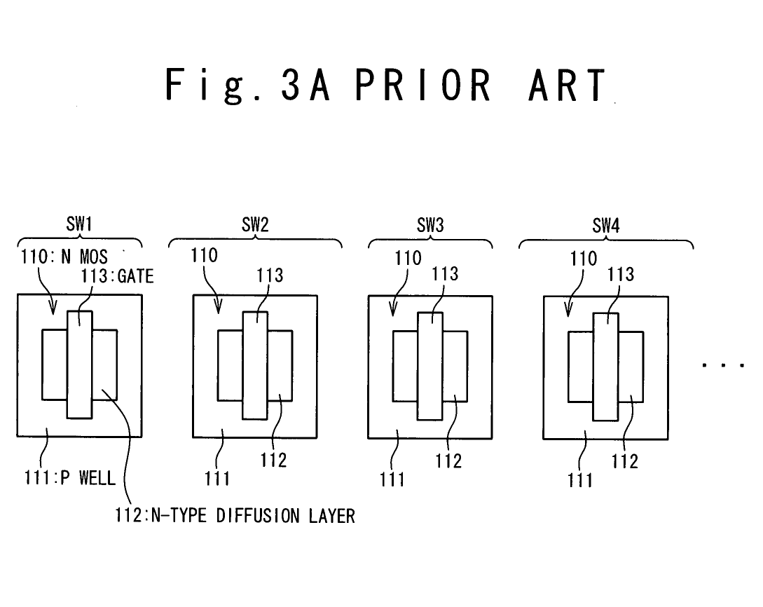

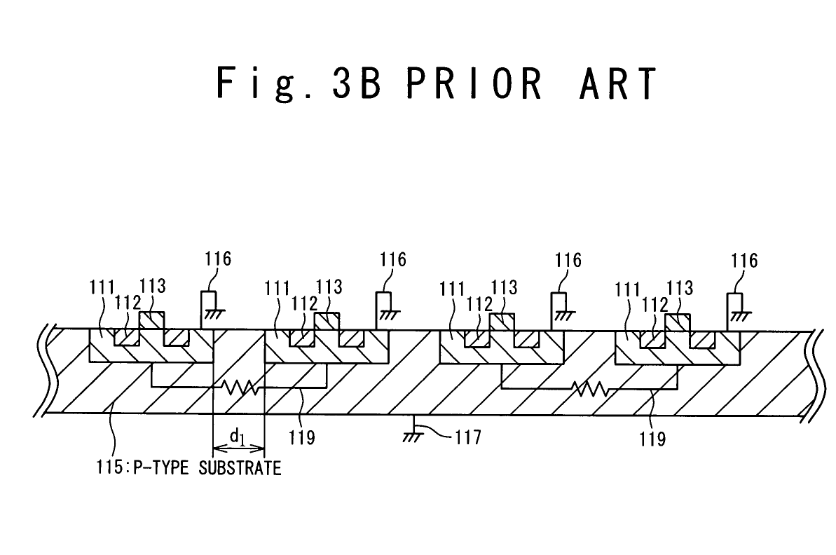

Also, since the circuit diagram of the switch circuit 3 of the present invention is similar to the circuit diagram of the switch circuit 103 shown in FIG. 2, its explanation is omitted. However, the NMOS transistor 110 of FIG. 2 corresponds to an NMOS transistor 10 in the present invention.

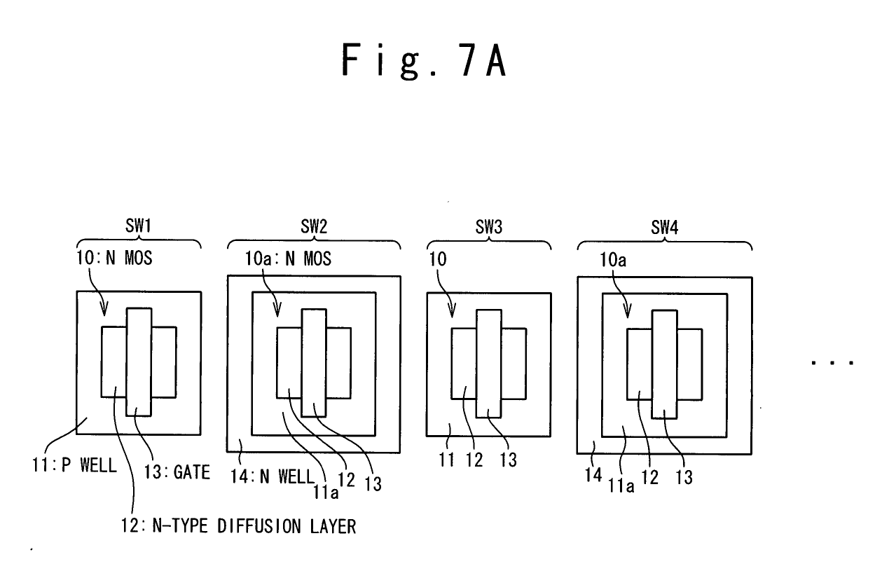

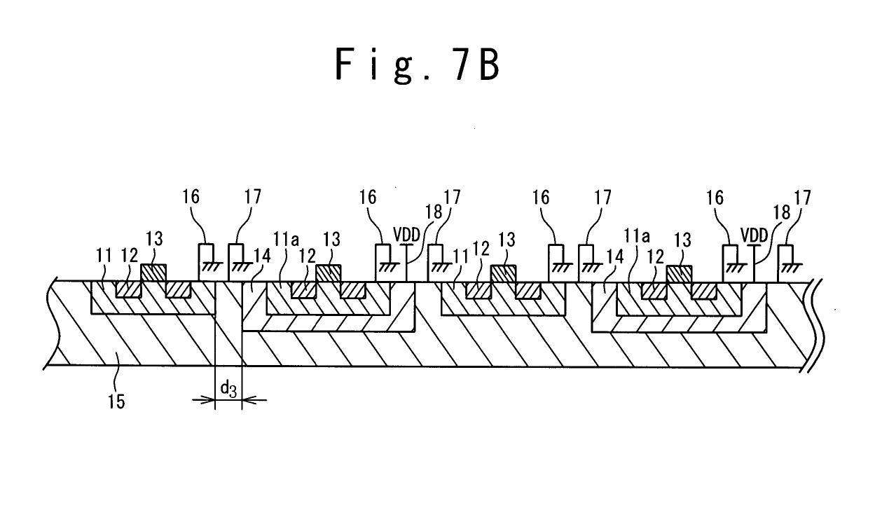

FIGS. 7A and 7B are a plan view and a cross sectional view showing the configuration of the switch circuit 3 according to the first embodiment of the present invention, respectively. The switch circuit 3 is composed of n (n is a natural number of 2 or more) analog switches SW (SW1 to SWn). This embodiment uses the NMOS transistor 10 as the switch SW. For example, about several hundred of analog switches may be provided to switch video input signals (n=several hundreds). The adjacent two of the NMOS transistors 10 are arranged such that their ends on the sides close to each other are separated by a distance d3. The distance of d3 is within the length of one NMOS transistor 10.

Of the respective switches SW (SW1 to SWn), the odd-numbered switch (SW (2k−1): k is a natural number) is composed of a P well 11 formed in a P-type substrate 15, and the NMOS transistor 10 formed in the P well 11. The NMOS transistor 10 is composed of two N-type diffusion layers 12 formed in the P well 11, and a gate 13 formed on the P-type substrate 15 between the two N-type diffusion layers 12. The P well 11 is connected to a ground line 16. The P-type substrate 15 near the P well 11 is connected to a ground line 17. Also, of the respective switches SW (SW1 to SWn), the even-numbered switch (SW (2k): k is a natural number) is composed of an N well 14 formed in the P-type substrate 15, a P well 11a formed in the N well 14 so as to be surrounded by the N well 14, and an NMOS transistor 10a formed in the P well 11a. The NMOS transistor 10a is composed of two N-type diffusion layers 12 formed in the P well 11a, and a gate 13 formed on the P-type substrate 15 between the two N-type diffusion layers 12. The P well 11a is connected to the ground line 16. The N well 14 is connected to a power source line 18. The P-type substrate 15 near the N well 14 is connected to the ground line 17.

In this way, in the present invention, the switch SW (2k−1) having the NMOS transistor 10 formed in the P well 11 which is not surrounded by any N well and the switch SW (2k) having the NMOS transistor 10a formed in the P well 11a which is surrounded by the N well 14 are alternately arranged. In this case, since the N well 14 is not formed for the switch SW (2k−1), the NMOS transistor 10 is not electrically separated from the P-type substrate 15. However, since the N well 14 is formed for the switch SW (2k), the NMOS transistor 10a is electrically separated from the P-type substrate 15. Thus, the signal leakage between the switch SW (2k) and the switch SW (2k−1), which are adjacent to each other, can be prevented by the N well 14 of the switch SW (2k). That is, it is possible to prevent the crosstalk between the switch SW (2k) and the switch SW (2k−1) which are adjacent to each other.

The signal mixture is extremely rare between the switches SW (SW (2k−1) and SW (2k+1)), for which the N wells 14 for electrically separating the P-type substrate 15 are not formed. This is because the switch SW (SW (2k)) is provided between those switches SW, and the distance between the switches SW is large. That is, it is possible to ignore the crosstalk between the switches SW (SW (2k−1) and SW (2k+1)) for which the N well 14 are not formed.

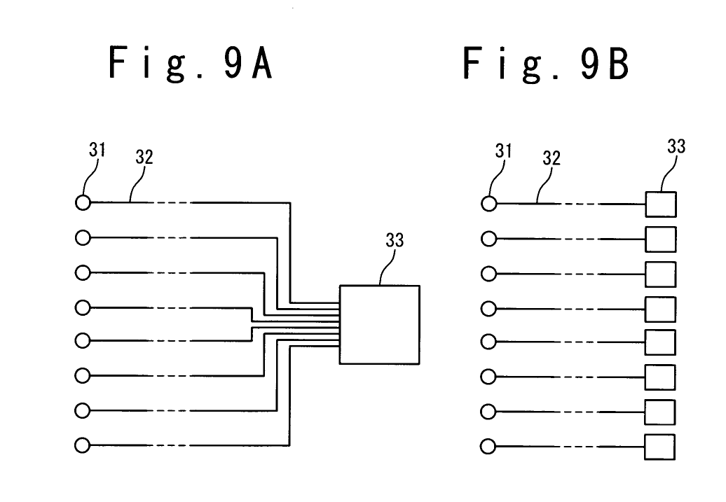

Also, the power source line 18 for the N well 14 is desired to be separated from a power source line 18 of a different N well 14. Thus, it is possible to prevent the interference of the signal through the power source line. FIGS. 9A and 9B are diagrams schematically showing the relation between the power source line and a pad of a semiconductor chip. FIG. 9A shows a situation in which a plurality of power source lines 32 extend from one bonding pad 33 in the semiconductor chip, and each of them is connected to the different N well 14. Here, the power source line 32 in this drawing is the power source line 18 in FIG. 7B. In this way, the power source line 32 is connected to the corresponding N well 14, and the respective power source lines 32 are not connected to each other to the bonding pad 33 or to a position as close as possible to the bonding pad 33. Therefore, it is possible to prevent the interference of the signal through the power source line.

Moreover, FIG. 9B shows that one power source line 32 extends from one bonding pad 33 in the semiconductor chip and is connected to one N well 14. However, the power source line 32 in this drawing is also the power source line 18 in FIG. 7B. In this way, the power source line 32 is connected to the corresponding N well 14, and the different bonding pad 33 is connected to each power source line 32. Therefore, it is possible to efficiently prevent the interference of the signal through the power source line.

It should be noted that the two methods may be combined and used in such a way that the method of FIG. 9A is used for some of the plurality of N wells 14 and the method of FIG. 9B is used for the other N wells 14. In that case, it is possible to increase the free degree of the design.

If the N-type diffusion layer regions (N wells 14) that are electrically separated from the P-type substrate 15 are formed for all of the switches, the different power source lines 18 (32) must be laid for all of the N wells 14 for the separation. However, in the present invention, since the number of the switches SW where the N wells 14 for the separation is provided is reduced to about a half, it is possible to reduce the number of the power source lines 18 to be separated. As a result, it is also possible to decrease the wiring region that must be formed therefore. Thus, according to the present invention, it is possible to efficiently prevent the signal mixture while suppressing the increase in the chip area to a minimum.

In the present invention, as the number of the switches SW becomes greater, its effect becomes more and more noticeable. That is, as the number of the switches SW that are included in the switch circuit 3 becomes greater and as the number of the switch circuits 3 adjacent to each other becomes greater, the influence of the signal mixture becomes severer. The increase in the chip area when the conventional technique is applied becomes very larger. However, in the application of the present invention, even in the foregoing case, it is possible to prevent the signal mixture while suppressing the increase in the chip area to the minimum.

FIGS. 9A and 9B show the dividing method of the plurality of power source lines. However, the dividing method similar to the case of the power source line can be applied to the dividing method of the plurality of ground lines 16, 17. Also, in that case, it possible to efficiently prevent the signal mixture while suppressing the increase in the chip area to a minimum.

It should be noted that, in the present invention, the switch circuit having the plurality of NMOS transistors on the P-type substrate has been described. However, this can be similarly applied to the switch circuit having the plurality of PMOS transistors on the N-type substrate. Moreover, this can be similarly applied to the switch circuit having the plurality of NMOS transistors on the P well, or the switch circuit having the plurality of PMOS transistors on the N well.

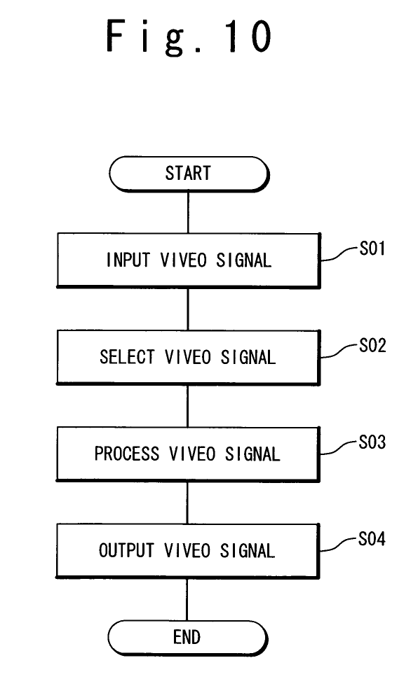

The operation of the first embodiment of the input signal processing circuit including the switch circuit of the present invention will be described below. FIG. 10 is a flowchart showing an operation of the input signal processing circuit according to the first embodiment of the present invention. Here, the operation of the input signal processing circuit 1 with regard to the G(Y) signal in FIG. 6 will be describe as the example. In this case, the switch circuit 3 has 5 switches SW1 to SW5.

As the video input signal, the G(Y) signals (G1(Y1) to G5(Y5) signals) of 5 elements are supplied to the switch circuit 3 (S01). The G1(Y1) to G5(Y5) signals are sent to the switches SW1 to SW5, respectively. The switch circuit 3 selects the G(Y) signal of one element from the G(Y) signals of 5 elements in accordance with a control signal (not shown) (S02). For example, when the G2(Y2) signal is selected, the switch SW2 is turned on. The selected one element G(Y) signal is outputted through the NMOS transistor 10a of the switch SW2 to the amplifying circuit 4. At this time, since the switch SW2 has the N well 14, the NMOS transistors 10 of the switches SW1 and SW3, which are adjacent to the switch SW2, never receive the influence of the G2(Y2) signal sent through the NMOS transistor 10a. That is, it is possible to prevent the signal mixture to the switches SW1, SW3 adjacent to each other. The amplifying circuit 4 amplifies and outputs the selected G(Y) signal. The signal processing circuit 5 carries out a predetermined signal process on the amplified G(Y) signal (S03) and outputs (S04).

According to the present invention, it is possible to prevent the interference of the signal between the switches SW adjacent to each other and ignore the crosstalk between the switches SW.

### Second Embodiment

The input signal processing circuit with the switch circuit according to the second embodiment of the present invention will be described below with reference to the attached drawings. At first, the configuration of the second embodiment of the switch circuit and input signal processing circuit of the present invention will be described. The configuration of the input signal processing circuit according to the second embodiment of the present invention is the same as the circuit block diagram of the first embodiment shown in FIG. 6. Thus, its description is omitted.

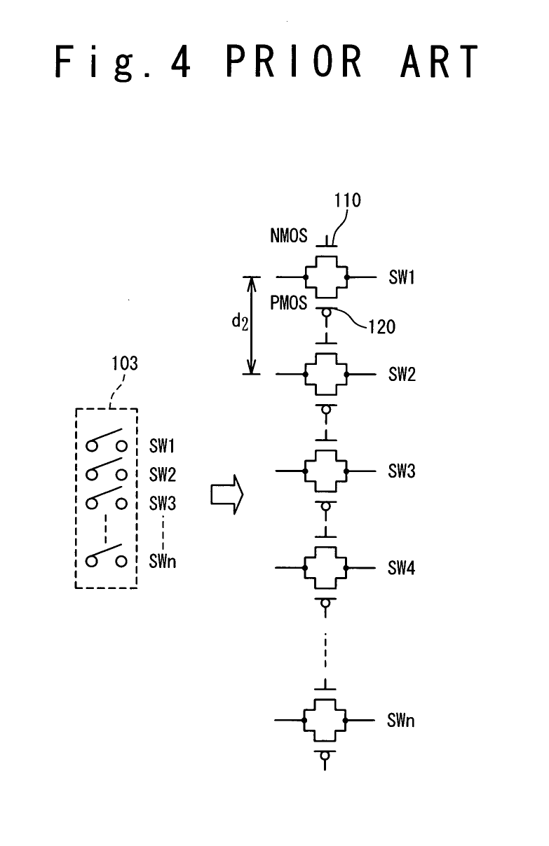

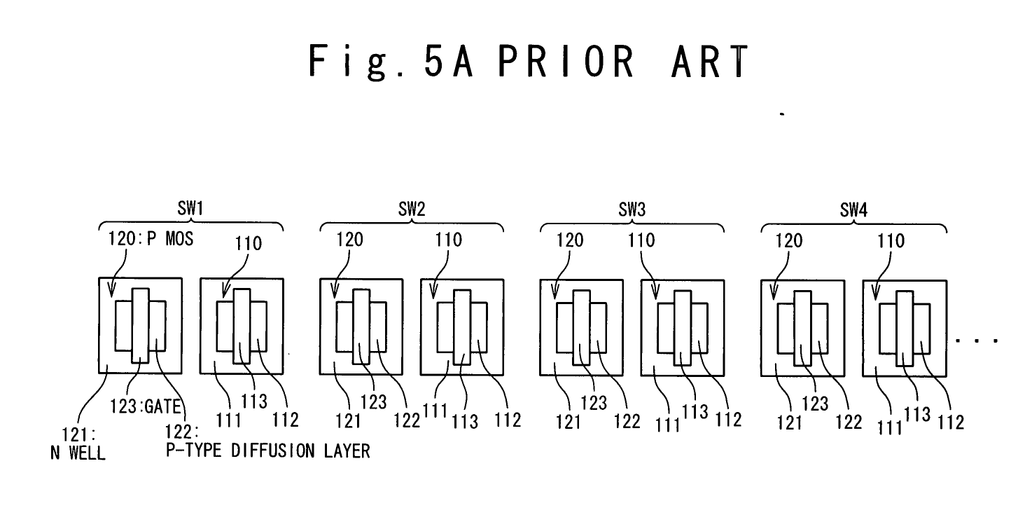

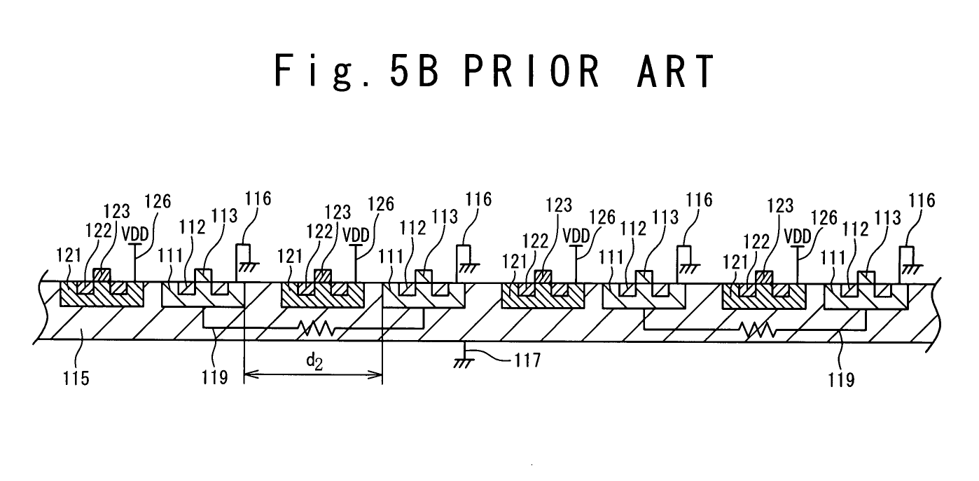

Since the circuit diagram of the switch circuit 3 of the present invention is similar to the circuit diagram of the switch circuit 103 shown in FIG. 4, its description is omitted. However, the NMOS transistor 110 and the PMOS transistor 120 in FIG. 4 correspond to the NMOS transistor 10 and the PMOS transistor 20 in the present invention, respectively.

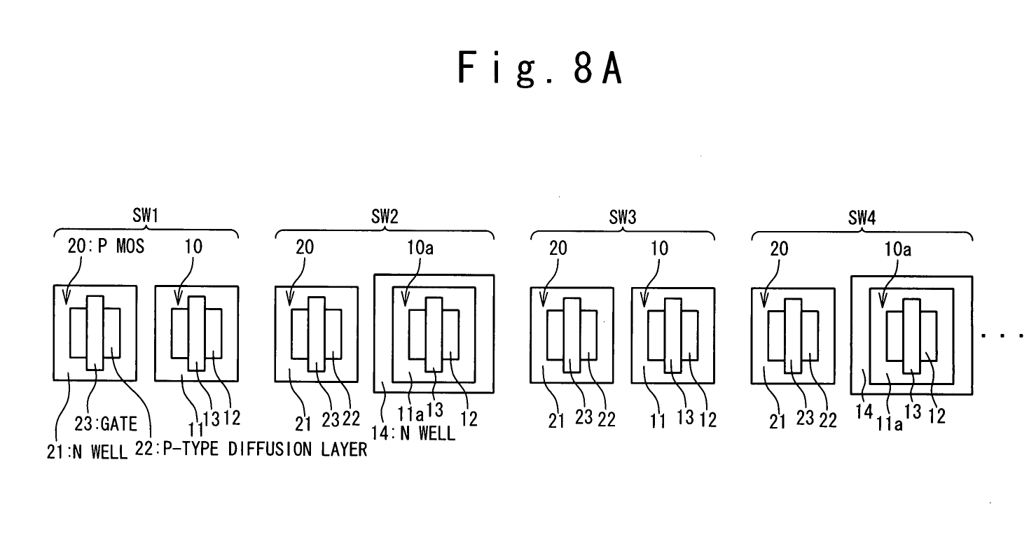

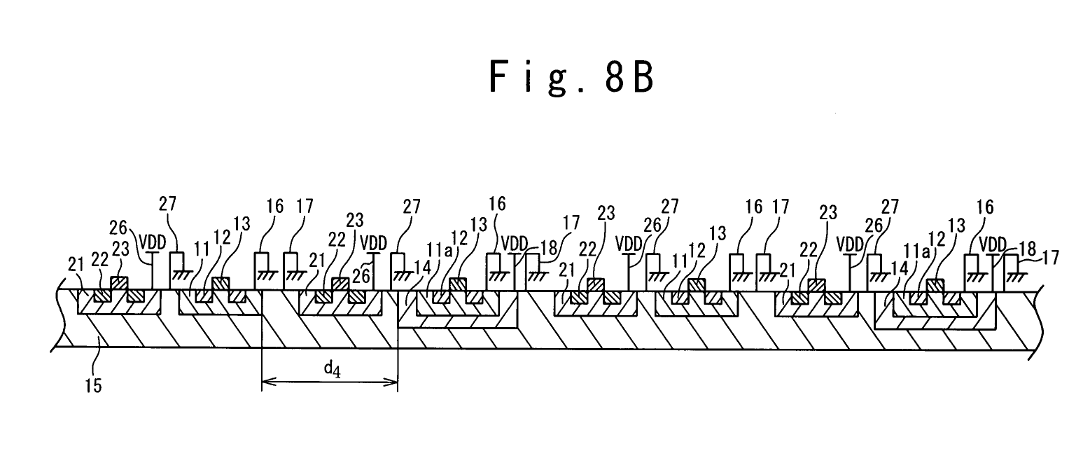

FIGS. 8A and 8B are a plan view and a sectional view showing the configuration of the switch circuit 3 according to the second embodiment of the present invention. The switch circuit 3 includes n (n is the natural number of 2 or more) analog switches SW (SW1 to SWn). In this example, a transfer gate which is the combination of the NMOS transistors 10 or 10a and the PMOS transistor 20 is used as the switches SW. For example, the about several hundred of analog switches may be provided to switch the video input signals (n=several hundreds). The NMOS transistors 10 of the switches SW adjacent to each other are arranged such that their ends on the sides close to each other are separated by a distance d4. The length of d4 is within the length of three NMOS transistor 10 or PMOS transistors.

Of the respective switches SW (SW1 to SWn), the odd-numbered switch SW (SW (2k−1): k is a natural number) is composed of a N well 21 formed in the P-type substrate 15, the PMOS transistor 20 formed in the N well 21, a P well 11 formed in the P-type substrate 15, and an NMOS transistor formed in the P well 11. The NMOS transistor 10 is composed of the two N-type diffusion layers 12 formed in the P well 11, and the gate 13 formed on the P-type substrate 15 between the two N-type diffusion layers 12. The P well 11 is connected to a ground line 16. The PMOS transistor 20 is composed of two P-type diffusion layers 22 formed in the N well 21, and a gate 23 formed on the P-type substrate 15 between two P-type diffusion layers 122. The N well 21 is connected to a power source line 26. Portions of the P-type substrate 15 near the P well 11 and near the N well 21 are connected to the ground line 17 and a ground line 27, respectively.

Of the respective switches SW (SW1 to SWn), the even-numbered switch SW (SW (2k): k is a natural number) is composed of an N well 14 formed in the P-type substrate 15, a P well 11a formed in the N well 14 so as to be surrounded by the N well 14, an NMOS transistor 10a formed in the P well 11a, the N well 21 formed in the P-type substrate 15, and the PMOS transistor 20 formed in the N well 21. The NMOS transistor 10a is composed of the two N-type diffusion layers 12 formed in the P well 11a, and the gate 13 formed on the P-type substrate 15 between the two N-type diffusion layers 12. The P well 11a is connected to the ground line 16. The N well 14 is connected to the power source line 18. The PMOS transistor 20 is composed of the two P-type diffusion layers 22 formed in the N well 21, and the gate 23 formed on the P-type substrate 15 between the two P-type diffusion layers 122. The N well 21 is connected to the power source line 26. The P well 11a is connected to the ground line 17, and the N well 14 is connected to the power source line 18. The portions of P-type substrates 15 near the N well 14 and near the N well 21 are connected to the ground line 17 and the ground line 27, respectively.

In this way, in the present invention, the switch SW (2k−1) having the NMOS transistor 10 that is not surrounded by the N-type diffusion layer region and the switch SW (2k) having the NMOS transistor 10a that is surrounded by the N well 14 are alternately arranged. In this case, since the switch SW (2k−1) is not surrounded by the N well 14, the NMOS transistor 10 is not electrically separated from the P-type substrate 15. However, since the switch SW (2k) is surrounded by the N well 14, the NMOS transistor 10a is electrically separated from the P-type substrate 15. Thus, the signal leakage between the switch SW (2k) and the switch SW (2k−1), which are adjacent to each other, can be prevented by the N well 14 of the switch SW (2k). That is, it is possible to prevent the crosstalk between the switch SW (2k) and the switch SW (2k−1) which are adjacent to each other.

The signal mixture is extremely rare between the switches SW (SW (2k−1) and SW (2k+1)). This is because the switch SW (2k) having the N well 14 is provided between those switches SW, and the distance between the switches SW is away. That is, it is possible to ignore the crosstalk between the switches SW (SW (2k−1) and SW (2k+1)) which are not surrounded by the N well 14. Also, the PMOS transistor 20 has no problem because it is electrically separated from the P-type substrate 15 in the N well 21.

The above facts can be applied to a 2-dimensional arrangement of the switches.

Also, the power source line 18 of the N well 14 is desired to be separated from the power source lines 18 of different N wells 14. Thus, it is possible to prevent the interference of the signal through the power source line. Since the dividing methods of the power source line with regard to FIGS. 9A and 9B are similar to those of the first embodiment, its description is omitted. Also, in this case, it is possible to prevent the interference of the signal through the power source line.

If the N-type diffusion layer regions (N wells 14) that are electrically separated from the P-type substrate 15 are formed for all of the switches, the different power source lines 18 (32) must be provided for all of the N wells 14 for the separation. However, in the present invention, since the number of the switches SW in which the N wells 14 for the separation are provided is reduced to about a half, it is possible to reduce the number of the power source lines 18 to be separated. As a result, it is also possible to decrease the wiring regions to be formed. Thus, according to the present invention, it is possible to efficiently prevent the signal mixture while suppressing the increase in the chip area to the minimum.

In the present invention, as the number of the switches SW becomes greater, its effect becomes more and more noticeable. That is, as the number of the switches SW that are included in the switch circuit 3 becomes greater and as the number of the switch circuits 3 becomes greater, the influence of the signal mixture becomes severer. Also, the increase in the chip area when the conventional technique is applied becomes very larger. However, in the application of the present invention, even in the foregoing case, it is possible to prevent the signal mixture while suppressing the increase in the chip area to the minimum.

FIGS. 9A and 9B shows the dividing methods of the plurality of power source lines. However, the dividing methods can be applied to the divisions of the plurality of ground lines 16, 17 and 27, like a case of the power source lines. Also, in that case, it possible to prevent the signal mixture while suppressing the increase in the chip area to the minimum.

It should be noted that, in the present invention, the switch circuit having the plurality of NMOS transistors on the P-type substrate has been described. However, this can be similarly applied to the switch circuit having the plurality of PMOS transistors on the N-type substrate. Moreover, this can be similarly applied to the switch circuit having the plurality of NMOS transistors on the P well, or the switch circuit having the plurality of PMOS transistors on the N well.

It should be noted that, the operation of the input signal processing circuit using the switch circuit according to the second embodiment of the present invention is substantially same as that of the input signal processing circuit using the switch circuit in the first embodiment. Thus, its description is omitted.

According to the present invention, it is possible to prevent the interference of the signal between the switches SW adjacent to each other and ignore the crosstalk between the switches SW.

Also, it is possible to efficiently prevent the crosstalk while suppressing the increase in the chip area.

What is claimed is:

1. A switch circuit comprising:
first switches; and
second switches,
wherein said first switches and said second switches are alternately arranged one by one,
a semiconductor substrate is of a first conductive type,
each of said first switches comprises a first transistor of a second conductive type which is opposite to that of said semiconductor substrate, and
each of said second switches includes a second transistor of said second conductive type, surrounded by an outer well of said second conductive type.

2. The switch circuit according to claim 1, wherein said first switch comprises:
a first well of said first conductive type formed in said semiconductor substrate; and
said first transistor of said second conductive type formed in said first well.

3. The switch circuit according to claim 2, wherein said second switch comprises:
said outer well formed in said semiconductor substrate;
a second well of said first conductive type formed in said outer well; and
said second transistor of said second conductive type formed in said second well.

4. The switch circuit according to claim 3, wherein said first well is connected to a first voltage by a first line,
said second well is connected to said first voltage by a second line, and
said outer well is connected to a second voltage by an outer well line.

5. The switch circuit according to claim 4, wherein each of portions of said semiconductor substrate near said first well and said outer well is connected to said first voltage.

6. The switch circuit according to claim 5, wherein said first conductive type is a P type, and said second conductive type is an N type,
said first voltage is a ground voltage, and
said second voltage is a power source voltage.

7. The switch circuit according to claim 5, wherein said outer well lines of said second switches are separated from each other in a neighborhood of said outer wells.

8. The switch circuit according to claim 3, wherein said first switch further comprises:
a third well of said second conductive type formed in said semiconductor substrate in a neighborhood of said first well; and
said third transistor of said first conductive type formed in said third well.

9. The switch circuit according to claim 8, wherein said second switch further comprises:
a fourth well of said second conductive type formed in said semiconductor substrate in a neighborhood of said outer well; and
said fourth transistor of said first conductive type formed in said fourth well.

10. The switch circuit according to claim 9, wherein said first well is connected to a first voltage by a first line,
said second well is connected to said first voltage by a second line,
said outer well is connected to a second voltage by an outer well line,
said third well is connected to said second voltage by a third line, and
said fourth well is connected to said second voltage by a fourth line.

11. The switch circuit according to claim 10, wherein each of portions of said semiconductor substrate near said first well, said third well, said fourth well and said outer well is connected to said first voltage.

12. The switch circuit according to claim 11, wherein said first conductive type is a P type, and said second conductive type is an N type,
said first voltage is a ground voltage, and
said second voltage is a power source voltage.

13. The switch circuit according to claim 11 wherein said outer well lines of said second switches are separated from each other in a neighborhood of said outer wells.

14. The switch circuit according to claim 11 wherein said first and second lines of said first and second switches are separated from each other in a neighborhood of said first and second wells.

15. An input signal processing circuit comprising:
a switch circuit configured to select one of a plurality of input signals in response to a control signal; and
a processing circuit configured to carry out a predetermined process to the selected signal by said switch circuit,
wherein said switch circuit comprises:
first switches; and
second switches,
said first switches and said second switches are alternately arranged one by one,
a semiconductor substrate is of a first conductive type,
each of said first switches comprises a first transistor of a second conductive type which is opposite to that of said semiconductor substrate, and
each of said second switches includes a second transistor of said second conductive type, surrounded by an outer well of said second conductive type.

16. The input signal processing circuit according to claim 15, wherein said first switch comprises:
a first well of said first conductive type formed in said semiconductor substrate; and
said first transistor of said second conductive type formed in said first well, and
said second switch comprises:
said outer well formed in said semiconductor substrate;
a second well of said first conductive type formed in said outer well; and
said second transistor of said second conductive type formed in said second well.

17. The input signal processing circuit according to claim 16, wherein said first well is connected to a first voltage by a first line,
said second well is connected to said first voltage by a second line,
said outer well is connected to a second voltage by an outer well line, and
each of portions of said semiconductor substrate near said first well and said outer well is connected to said first voltage.

18. The input signal processing circuit according to claim 16, wherein said first switch further comprises:
a third well of said second conductive type formed in said semiconductor substrate in a neighborhood of said first well; and
said third transistor of said first conductive type formed in said third well, and
said second switch further comprises:
a fourth well of said second conductive type formed in said semiconductor substrate in a neighborhood of said outer well; and
said fourth transistor of said first conductive type formed in said fourth well.

19. The switch circuit according to claim 18, wherein said first well is connected to a first voltage by a first line,
said second well is connected to said first voltage by a second line,
said outer well is connected to a second voltage by an outer well line,
said third well is connected to said second voltage by a third line, and
said fourth well is connected to said second voltage by a fourth line.

20. The switch circuit according to claim 19, wherein each of portions of said semiconductor substrate near said first well, said third well, said fourth well and said outer well is connected to said first voltage.
